(19) United States
(12) Patent Application Publication
(10) Pub. No.: US 2023/0066154 A1
(43) Pub. Date: Mar. 2, 2023

(54) SEMICONDUCTOR DEVICE AND METHOD OF MANUFACTURING THE SAME

(71) Applicant: FUJI ELECTRIC CO., LTD., Kawasaki-shi (JP)

(72) Inventor: Kazuo ENOMOTO, Matsumoto-city (JP)

(73) Assignee: FUJI ELECTRIC CO., LTD., Kawasaki-shi (JP)

(21) Appl. No.: 17/850,688

(22) Filed: Jun. 27, 2022

(30) Foreign Application Priority Data
Aug. 27, 2021 (JP) 2021-139027

(51) Int. Cl. H01L 23/367; H01L 23/31; H01L 21/48

(52) U.S. Cl. CPC H01L 23/3675; H01L 23/3142; H01L 21/4878; H01L 23/3121; H01L 25/072

(57) ABSTRACT

A semiconductor device includes a semiconductor unit including a semiconductor chip, a cooling plate having a cooling front surface on which the semiconductor unit is disposed, a case disposed along an outer edge of the cooling front surface at the outer edge via an adhesive so as to surround the semiconductor unit, and a sealing member sealing the semiconductor unit disposed on the cooling plate inside the case. The cooling plate has an interlocking portion, the interlocking portion including a recess in the cooling front surface, and an engagement surface disposed inside the recess and being inclined at an acute angle with respect to the cooling front surface.

### CROSS-REFERENCE TO RELATED APPLICATION

This application is based upon and claims the benefit of priority of the prior Japanese Patent Application No. 2021-139027, filed on Aug. 27, 2021, the entire contents of which are incorporated herein by reference.

### BACKGROUND OF THE INVENTION

### 1. Field of the Invention

The embodiments discussed herein relate to a semiconductor device and a method of manufacturing the same.

### 2. Background of the Related Art

Semiconductor devices include power devices and are used as power conversion devices. For example, power devices are insulated gate bipolar transistors (IGBTs) and power metal oxide semiconductor field effect transistors (MOSFETs). A semiconductor device has a configuration in which semiconductor chips including power devices and an insulated circuit substrate, which are disposed over a cooling plate made of metal, are accommodated in a case and the inside of the case is sealed with a sealing member.

Please see, for example, Japanese Laid-open Patent Publication No. 2013-115297.

In such a semiconductor device, a sealing member and a cooling plate adhere to each other with their adhesion. The adhesion reduces with the aging of the semiconductor device, and it is difficult to maintain the adhesion as time passes. When the adhesion strength reduces, the sealing member may be separated, and moisture may enter the separated region, which results in failing to maintain the insulation of the semiconductor chips, insulated circuit substrate, and others. In addition, when the adhesion strength reduces, the semiconductor chips and insulated circuit substrate may be separated from the case. This reduces the reliability of the semiconductor device.

### SUMMARY OF THE INVENTION

According to one aspect, there is provided a semiconductor device, including: a semiconductor unit including a semiconductor chip; a cooling plate having a cooling front surface on which the semiconductor unit is disposed; a case disposed along an outer edge of the cooling front surface via an adhesive so as to surround the semiconductor unit; and a sealing member sealing the semiconductor unit disposed on the cooling plate inside the case, wherein the cooling plate has an interlocking portion, the interlocking portion including a recess in the cooling front surface, and an engagement surface disposed inside the recess and being inclined at an acute angle with respect to the cooling front surface.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a sectional view of the semiconductor device according to the first embodiment;

FIG. 3 is a plan view of a semiconductor unit provided in the semiconductor device according to the first embodiment;

FIG. 4 is a perspective view of an interlocking portion formed in a cooling plate provided in the semiconductor device according to the first embodiment;

FIG. 5 is a sectional view of the interlocking portion formed in the cooling plate provided in the semiconductor device according to the first embodiment;

FIG. 6 is a flowchart illustrating a method of manufacturing the semiconductor device according to the first embodiment;

FIG. 7 is a view for describing a mounting step included in the method of manufacturing the semiconductor device according to the first embodiment;

FIG. 8 is a view for describing an attachment step included in the method of manufacturing the semiconductor device according to the first embodiment;

FIG. 9 is a flowchart illustrating a method of forming the interlocking portion in the cooling plate according to the first embodiment;

FIG. 10 is a plan view for describing a recess forming step included in the method of forming the interlocking portion in the cooling plate according to the first embodiment;

FIG. 11 is a sectional view for describing the recess forming step included in the method of forming the interlocking portion in the cooling plate according to the first embodiment;

FIG. 12 is a view for describing a tilting step included in the method of forming the interlocking portion in the cooling plate according to the first embodiment (part 1);

FIG. 13 is a view for describing the tilting step included in the method of forming the interlocking portion in the cooling plate according to the first embodiment (part 2);

FIG. 14 is a sectional view of an interlocking portion formed in a cooling plate provided in a semiconductor device according to a modification example 1-1 of the first embodiment;

FIG. 15 is a plan view of a semiconductor device according to a second embodiment;

FIG. 16 is a plan view of an interlocking portion formed in a cooling plate provided in the semiconductor device according to the second embodiment;

FIG. 17 is a sectional view of the interlocking portion formed in the cooling plate provided in the semiconductor device according to the second embodiment;

FIG. 18 is a plan view of an interlocking portion formed in a cooling plate provided in a semiconductor device according to a modification example 2-1 of the second embodiment;

FIG. 19 is a sectional view of an interlocking portion formed in a cooling plate provided in a semiconductor device according to a third embodiment;

FIG. 20 is a plan view of the interlocking portion formed in the cooling plate provided in the semiconductor device according to the third embodiment;

FIG. 21 is a sectional view of an interlocking portion formed in a cooling plate provided in a semiconductor device according to a fourth embodiment;

FIG. 22 is a plan view of the interlocking portion formed in the cooling plate provided in the semiconductor device according to the fourth embodiment; and

FIG. 23 is a sectional view of an interlocking portion formed in a cooling plate provided in a semiconductor device according to a fifth embodiment.

### DETAILED DESCRIPTION OF THE INVENTION

Hereinafter, several embodiments will be described with reference to the accompanying drawings. In the following description, the terms “front surface” and “upper surface” refer to surfaces facing up (in the positive Z direction) in a semiconductor device. Similarly, the term “up” refers to an upward direction (the positive Z direction) in the semiconductor device. The terms “rear surface” and “lower surface” refer to surfaces facing down (in the negative Z direction) in the semiconductor device. Similarly, the term “down” refers to a downward direction (the negative Z direction) in the semiconductor device. The same directionality applies to drawings other than the drawings of the semiconductor device, as appropriate. The terms “front surface,” “upper surface,” “up,” “rear surface,” “lower surface,” “down,” and “side surface” are used for convenience to describe relative positional relationships, and do not limit the technical ideas of the embodiments. For example, the terms “up” and “down” are not always related to the vertical direction to the ground. That is, the “up” and “down” directions are not limited to the gravity direction. In addition, in the following description, a component contained at a volume ratio of 80 vol % or more is called a “principal component.”

### First Embodiment

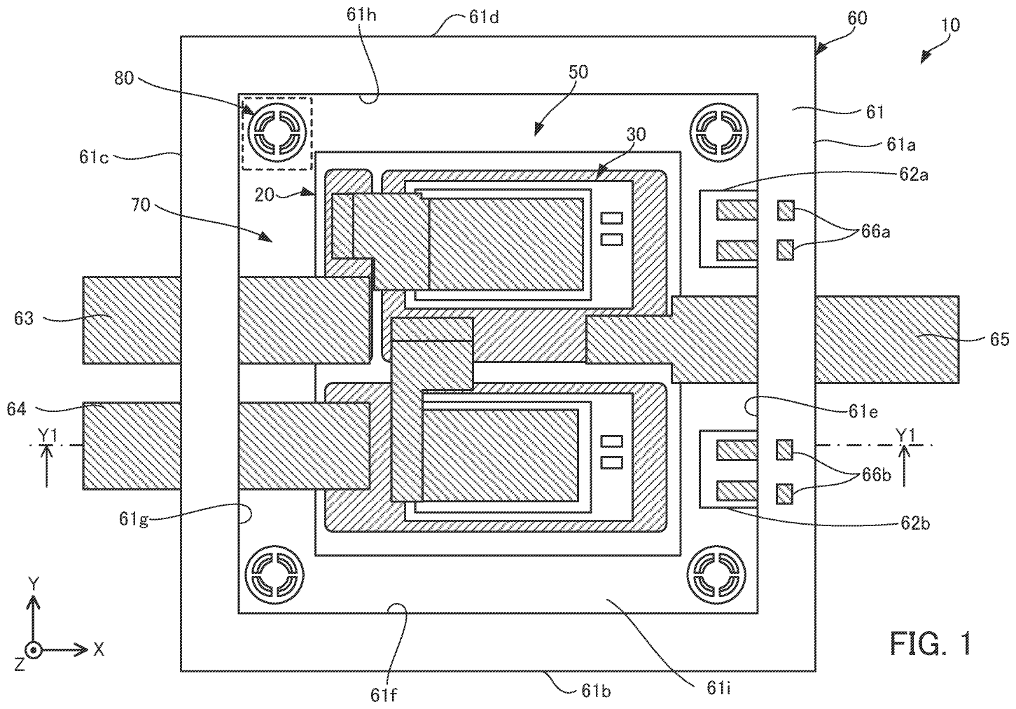

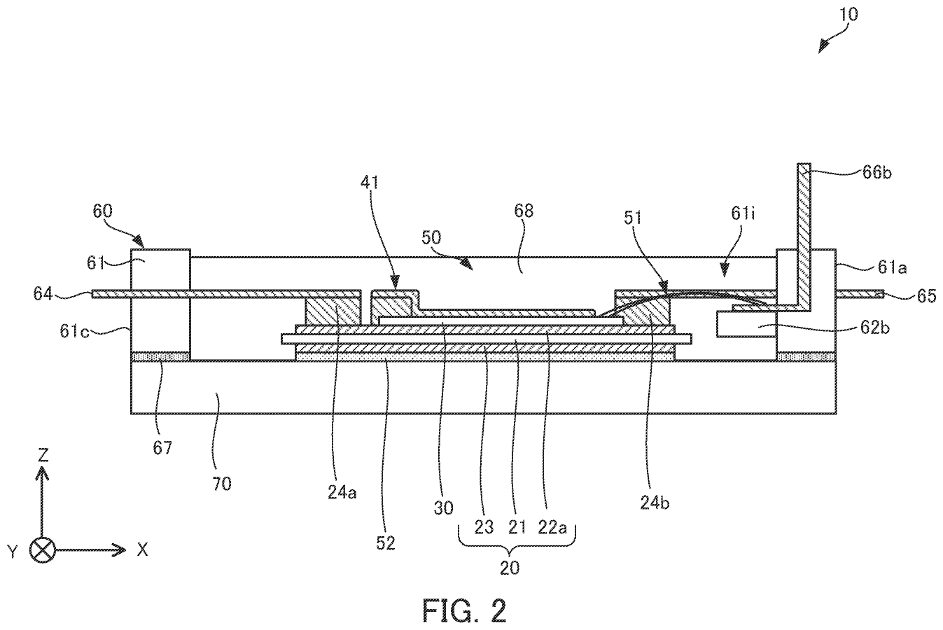

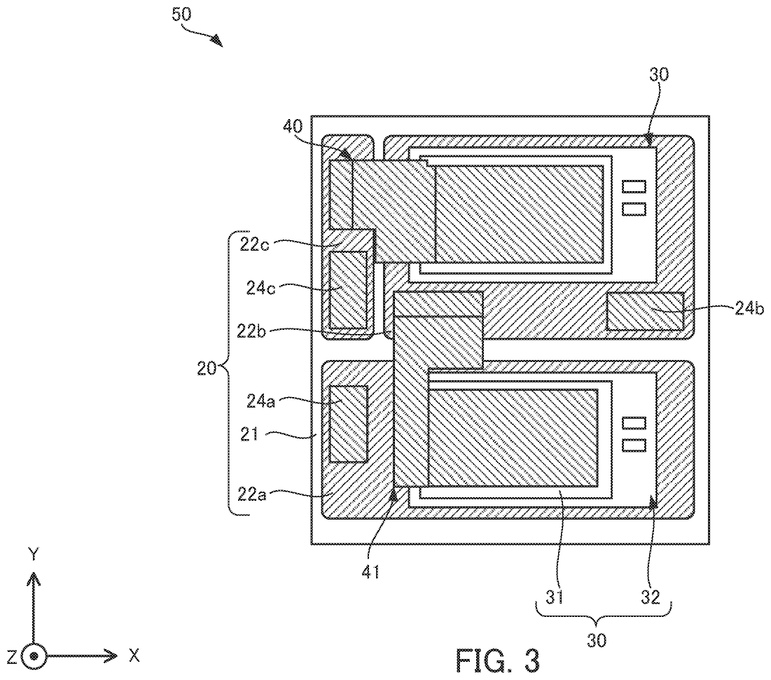

A semiconductor device of a first embodiment will be described with reference to FIGS. 1 to 3. FIG. 1 is a plan view of the semiconductor device according to the first embodiment, FIG. 2 is a sectional view of the semiconductor device according to the first embodiment, and FIG. 3 is a plan view of a semiconductor unit provided in the semiconductor device according to the first embodiment. In this connection, the illustration of a sealing member 68 is omitted in FIG. 1. FIG. 2 is a sectional view taken along the dot-dashed line Y1-Y1 of FIG. 1.

The semiconductor device 10 has a semiconductor unit 50, a cooling plate 70 on which the semiconductor unit 50 is disposed, a case 60 disposed on the cooling plate 70 so as to surround the semiconductor unit 50, and the sealing member 68 sealing the semiconductor unit 50 inside the case 60.

The semiconductor unit 50 includes an insulated circuit substrate 20, and semiconductor chips 30, conduction blocks 24a, 24b, and 24c, and wiring members 40 and 41 that are disposed on the insulated circuit substrate 20.

The insulated circuit substrate 20 is rectangular in plan view. The insulated circuit substrate 20 includes an insulating board 21, circuit patterns 22a, 22b, and 22c disposed on the front surface of the insulating board 21, and a metal plate 23 disposed on the rear surface of the insulating board 21. The semiconductor chips 30 are mechanically and electrically bonded to the front surfaces of the circuit patterns 22a and 22b with a bonding member (not illustrated). In addition, the conduction blocks 24a, 24b, and 24c are mechanically and electrically bonded to the front surfaces of the circuit patterns 22a, 22b, and 22c with the bonding member. The wiring member 40 mechanically and electrically connects the semiconductor chip 30 on the circuit pattern 22b and the circuit pattern 22c. The wiring member 41 mechanically and electrically connects the semiconductor chip 30 on the circuit pattern 22a and the circuit pattern 22b.

The insulating board 21 is rectangular in plan view. The corners of the insulating board 21 may be chamfered in an R- or C-shape. The insulating board 21 is made of ceramics with high thermal conductivity. For example, the ceramics are made of a material containing aluminum oxide, aluminum nitride, or silicon nitride as a principal component. The thickness of the insulating board 21 is in the range of 0.2 mm to 2.0 mm, inclusive.

The circuit patterns 22a, 22b, and 22c are formed over the entire surface of the insulating board 21 except the edges of the insulating board 21. More preferably, in plan view, sides of the circuit patterns 22a, 22b, and 22c facing the perimeter of the insulating board 21 are aligned with the corresponding sides of the metal plate 23 facing the perimeter of the insulating board 21. With this configuration, the insulated circuit substrate 20 maintains the stress balance between the circuit patterns 22a, 22b, and 22c and the metal plate 23 on the rear surface of the insulating board 21. Damage, such as excess warpage and cracks, to the insulating board 21 is prevented. More specifically, each circuit pattern 22a, 22b, and 22c is rectangular in plan view. On the front surface of the insulating board 21, the circuit pattern 22a is formed from one end to the other end of the insulating board 21 in the X direction and on the negative Y direction side. On the front surface of the insulating board 21, the circuit pattern 22b is formed from one end of the insulating board 21 in the positive X direction to a point that is close to but does not reach the other end thereof in the negative X direction and on the positive Y direction side. On the front surface of the insulating board 21, the circuit pattern 22c is formed adjacent to the circuit pattern 22b in the negative X direction.

The thicknesses of the circuit patterns 22a, 22b, and 22c are in the range of 0.1 mm to 2.0 mm, inclusive. The circuit patterns 22a, 22b, and 22c are made of a metal with high electrical conductivity. Examples of the metal include copper, aluminum, and an alloy containing at least one of these. Plating may be performed on the surfaces of the circuit patterns 22a, 22b, and 22c to improve their corrosion resistance. Examples of the plating material used here include nickel, a nickel-phosphorus alloy, and a nickel-boron alloy. The circuit patterns 22a, 22b, and 22c are formed on the insulating board 21 by forming a metal plate on the front surface of the insulating board 21 and performing etching or another on the metal plate. Alternatively, the circuit patterns 22a, 22b, and 22c may be cut out from a metal plate in advance and press-bonded to the front surface of the insulating board 21. In this connection, the circuit patterns 22a, 22b, and 22c are just an example. The number of circuit patterns and the shapes, sizes and others thereof may be determined as appropriate.

The metal plate 23 is rectangular in plan view. The corners of the metal plate 23 may be chamfered in an R- or C-shape. The metal plate 23 is smaller in size than the insulating board 21 and is formed over the entire rear surface of the insulating board 21 except the edges of the insulating board 21. The metal plate 23 is made using a metal with high thermal conductivity as a principal component. Examples of the metal include copper, aluminum, and an alloy containing at least one of these. The thickness of the metal plate 23 is in the range of 0.1 mm to 2.0 mm, inclusive. Plating may be performed to improve the corrosion resistance of the metal plate 23. Examples of the plating material used here include nickel, a nickel-phosphorus alloy, and a nickel-boron alloy.

For the insulated circuit substrate 20 including the insulating board 21, circuit patterns 22a, 22b, and 22c, and metal plate 23 as described above, a direct copper bonding (DCB) substrate or an active metal brazed (AMB) substrate may be used, for example.

The semiconductor chips 30 include power device elements that are made of silicon, silicon carbide, or gallium nitride. The thicknesses of the semiconductor chips 30 are in the range of 40 μm to 250 μm, inclusive, for example. A power device element may be a switching element or a diode element. The switching element may be an IGBT or a power MOSFET, for example. For example, the semiconductor chip 30 of this type has a drain electrode (or a collector electrode) serving as a main electrode on the rear surface thereof and has a gate electrode and a source electrode (or an emitter electrode) serving as a control electrode and a main electrode on the front surface thereof.

The diode element is a free wheeling diode (FWD) such as a Schottky barrier diode (SBD) or a P-intrinsic-N (PiN) diode, for example. The semiconductor chip 30 of this type has a cathode electrode serving as a main electrode on the rear surface thereof and has an anode electrode serving as a main electrode on the front surface thereof. At least one of the switching element and the diode element is selected for each semiconductor chip 30 according to necessity, and the rear surfaces of the selected elements are mechanically and electrically bonded to the circuit patterns 22a and 22b with a bonding member.

In addition, as each semiconductor chip 30, a reverse-conducting (RC)-IGBT chip that has the functions of both IGBT and FWD may be used. Note that FIG. 3 exemplifies the case where the semiconductor chips 30 are RC-IGBTs. Each semiconductor chip 30 has an output electrode 31, which is an emitter electrode, and a control electrode 32, which is a gate electrode, on the front surface thereof and has an input electrode (not illustrated), which is a collector electrode, on the rear surface thereof. The semiconductor chips 30 of this type are bonded to the circuit patterns 22a and 22b with their control electrodes 32 facing in the positive X direction and their output electrodes 31 facing in the negative X direction as viewed in FIG. 3.

The wiring members 40 and 41 are lead frames, for example, and are made of a metal with high electrical conductivity. Examples of the metal include copper, aluminum, and an alloy containing at least one of these. Plating may be performed on the surfaces of the wiring members 40 and 41 to improve their corrosion resistance. Examples of the plating material used here include nickel, a nickel-phosphorus alloy, and a nickel-boron alloy.

The wiring member 40 straddles the gap between the circuit patterns 22b and 22c, with one end thereof bonded to the circuit pattern 22c with a bonding member and the other end thereof bonded to the output electrode 31 of the semiconductor chip 30 disposed on the circuit pattern 22b with the bonding member. The wiring member 41 straddles the gap between the circuit patterns 22b and 22a, with one end thereof bonded to the circuit pattern 22b with the bonding member and the other end thereof bonded to the output electrode 31 of the semiconductor chip 30 disposed on the circuit pattern 22a with the bonding member. Instead of the bonding using the bonding member, the wiring members 40 and 41 may be bonded to the circuit patterns 22c and 22b by ultrasonic bonding or laser welding.

The conduction blocks 24a to 24c are block-shaped (cubes). The conduction blocks 24a to 24c are made of a metal with high electrical conductivity. Examples of the metal include copper, aluminum, and an alloy containing at least one of these. Plating may be performed on the surfaces of the conduction blocks 24a to 24c to improve their corrosion resistance. Examples of the plating material used here include nickel, a nickel-phosphorus alloy, and a nickel-boron alloy. The conduction blocks 24a to 24c are mechanically and electrically bonded with a bonding member.

The conduction block 24a is bonded to an end portion of the circuit pattern 22a in the negative X direction with the bonding member as viewed in FIG. 3. The conduction block 24b is bonded to an end portion of the circuit pattern 22b in the X direction on the negative Y direction side with the bonding member as viewed in FIG. 3. The conduction block 24c is bonded to an end portion of the circuit pattern 22c on the negative Y direction side as viewed in FIG. 3.

All the bonding members mentioned in the above description are a solder or a sintered metal. A lead-free solder is used as the solder. For example, the lead-free solder contains, as a principal component, an alloy containing at least two of tin, silver, copper, zinc, antimony, indium, and bismuth. In addition, the solder may contain an additive. Examples of the additive include nickel, germanium, cobalt, and silicon. The solder containing the additive exhibits improved wettability, gloss, and bond strength, which results in improving the reliability. Examples of the metal used for the sintered metal include silver or a silver alloy.

The cooling plate 70 is rectangular in plan view. The thickness of the cooling plate 70 is in the range of 1.0 mm to 10.0 mm, inclusive and is, for example, approximately 3.0 mm. The cooling plate 70 is made using a metal with high thermal conductivity as a principal component. Examples of the metal include copper, aluminum, and an alloy containing at least one of these. Plating may be performed to improve the corrosion resistance of the cooling plate 70. Examples of the plating material used here include nickel, a nickel-phosphorus alloy, and a nickel-boron alloy.

In addition, the rear surface of the semiconductor unit 50 (the metal plate 23 of the insulated circuit substrate 20) is bonded to the front surface (cooling front surface) of the cooling plate 70 with a bonding member 52. In this connection, the semiconductor unit 50 is bonded to the central portion of the front surface of the cooling plate 70, for example. In this case, the bonding member 52 may be the above-described solder or sintered metal. Alternatively, a brazing filler metal or a thermal interface material may be used. For example, the brazing filler metal contains at least any of an aluminum alloy, a titanium alloy, a magnesium alloy, a zirconium alloy, and a silicon alloy as a principal component. In the case of using the brazing filler metal as the boding member, the rear surface (the metal plate 23) of the insulated circuit substrate 20 is bonded to the determined area of the front surface of the cooling plate 70 by brazing processing. The term “thermal interface material” is a generic term for various materials such as thermally conductive grease, elastomer sheet, room temperature vulcanization (RTV) rubber, gel, and phase change materials, for example. The grease is silicone mixed with a metal oxide filler, for example. In this case, for example, the cooling unit is made of a material with high thermal conductivity, such as aluminum, iron, silver, copper, or an alloy containing at least one of these.

In addition, interlocking portions 80 are formed in the front surface of the above cooling plate 70. In the cooling plate 70 to which a case 60, which will be described later, is attached, the interlocking portions 80 are formed at the four corners inside the case 60. The positions and quantity of the interlocking portions 80 are not limited to this configuration. The interlocking portions 80 are formed in areas where the semiconductor unit 50 is not disposed in the front surface of the cooling plate 70 inside the case 60. That is, the interlocking portions 80 are not formed in areas of the cooling plate 70 where the case 60 and the semiconductor unit 50 are disposed. The interlocking portions 80 will be described in detail later.

The case 60 includes a frame 61, and external connection terminals 63, 64 and 65 and control terminals 66a and 66b that are integrally formed with the frame 61. The frame 61 has a loop shape in plan view. The frame 61 has outer side surfaces 61a, 61b, 61c, and 61d that are arranged in this order and bound the periphery of the frame 61, and has inner wall surfaces 61e, 61f, 61g, and 61h that are arranged in this order and surround a housing space 61i. In addition, the frame 61 has terminal blocks 62a and 62b disposed on the inner wall surface 61e with a gap therebetween. The terminal blocks 62a and 62b project from the inner wall surface 61e toward the housing space 61i in perpendicular to the inner wall surface 61e. The terminal blocks 62a and 62b each have a front surface (the X-Y plane) that is perpendicular to the inner wall surface 61e and faces upward (in the positive Z direction). This frame 61 is disposed along the outer edge of the cooling plate 70 via an adhesive 67 so as to surround the semiconductor unit 50. In this connection, the adhesive 67 has a heatproof temperature of approximately 100° C. to 200° C. Epoxy-based, silicone-based, and acrylic-based organic adhesives may be used. In addition, the adhesive 67 in paste or sheet form may be used.

The external connection terminals 63, 64, and 65 are made of a metal with high electrical conductivity. Examples of the metal include copper, aluminum, and an alloy containing at least one of these. Plating may be performed on the surfaces of the external connection terminals 63, 64, and 65 to improve their corrosion resistance. Examples of the plating material used here include nickel, a nickel-phosphorus alloy, and a nickel-boron alloy. The external connection terminals 63, 64, and 65 are mechanically and electrically bonded with a bonding member.

The external connection terminals 63 and 64 are disposed in the frame 61, penetrating through the outer side surface 61c and inner wall surface 61g of the frame 61. One end (inside the frame 61) of the external connection terminal 63 is mechanically and electrically bonded to the conduction block 24c. One end (inside the frame 61) of the external connection terminal 64 is mechanically and electrically bonded to the conduction block 24a. The other end (outside the frame 61) of each external connection terminal 63 and 64 extends to the outside in perpendicular to the outer side surface 61c. The external connection terminal 65 is disposed in the frame 61, penetrating through the outer side surface 61a and inner wall surface 61e of the frame 61. One end (inside the frame 61) of the external connection terminal 65 is mechanically and electrically bonded to the conduction block 24b. The other end (outside the frame 61) of the external connection terminal 65 extends to the outside in perpendicular to the outer side surface 61a. The one end of each external connection terminal 63, 64, and 65 is bonded to the corresponding one of the conduction blocks 24c, 24a and 24b with the above-described bonding member or by ultrasonic bonding or laser welding.

The control terminals 66a and 66b are made of a metal with high electrical conductivity. Examples of the metal include copper, aluminum, and an alloy containing at least one of these. Plating may be performed on the surfaces of the control terminals 66a and 66b to improve their corrosion resistance. Examples of the plating material used here include nickel, a nickel-phosphorus alloy, and a nickel-boron alloy. The control terminals 66a and 66b are mechanically and electrically bonded with a bonding member.

Each control terminal 66a and 66b is L-shaped in side view (in the X-Z plane). One end of each control terminal 66a and 66b is exposed on the front surface of the corresponding one of the terminal blocks 62a and 62b. The control terminals 66a and 66b pass through a portion of the frame 61 sandwiched between the outer side surface 61a and inner wall surface 61e, and the other end of each control terminal 66a and 66b extends vertically upward (in the Z direction) from the front surface of the frame 61. The one end of each control terminal 66a and the control electrode 32 of the semiconductor chip 30 disposed on the circuit pattern 22b are mechanically and electrically connected to each other with a wire 51. The one end of each control terminal 66b and the control electrode 32 of the semiconductor chip 30 disposed on the circuit pattern 22a are mechanically and electrically connected to each other with a wire 51. These wires 51 are made of a material with high electrical conductivity. Examples of the material include gold, silver, copper, aluminum, and an alloy containing at least one of these. The diameters of the wires 51 are in the range of 110 μm to 400 μm, inclusive, for example.

The case 60 is made of a resin. This resin contains a thermoplastic resin as a principal component. Examples of the thermoplastic resin include a polyphenylene sulfide resin, a polybutylene terephthalate resin, a polybutylene succinate resin, a polyamide resin, and an acrylonitrile-butadiene-styrene resin. A metal plate including the external connection terminals 63, 64, and 65 and control terminals 66a and 66b is placed in a predetermined mold. The mold is filled with such a resin, the rein is solidified, the mold is removed, and then excess parts are cut off from the metal plate. By integrally molding the frame 61, external connection terminals 63, 64, and 65, and control terminals 66a and 66b in this manner, the case 60 is obtained.

The sealing member 68 seals the case 60 up to such a height as to seal the semiconductor unit 50 and wires 51, and the external connection terminals 63, 64 and 65 and control terminals 66a and 66b placed inside the case 60. The sealing member 68 also seals the interlocking portions 80 as will be described later. The sealing member 68 contains a thermosetting resin and a filler that is contained in the thermosetting resin. Examples of the thermosetting resin include an epoxy resin, a phenolic resin, and a maleimide resin. Examples of the filler include silicon dioxide, aluminum oxide, boron nitride, and aluminum nitride. An example of the sealing member 68 contains an epoxy resin and a filler. In this connection, at least one of the fillers listed above is used.

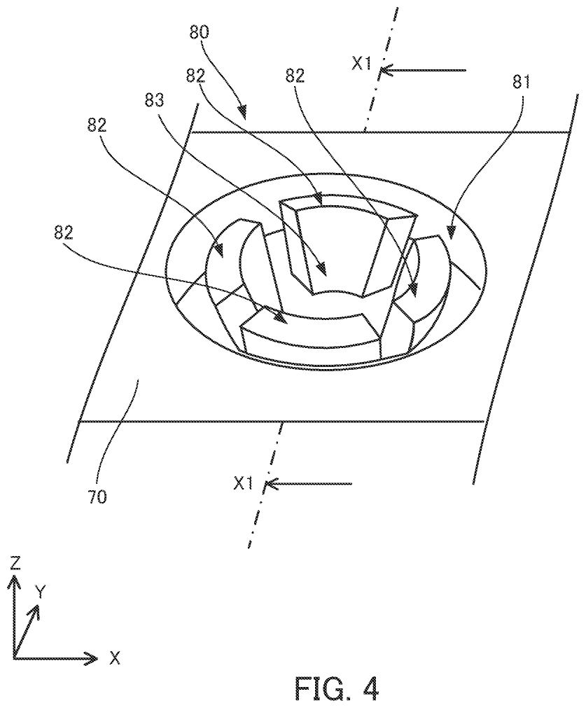

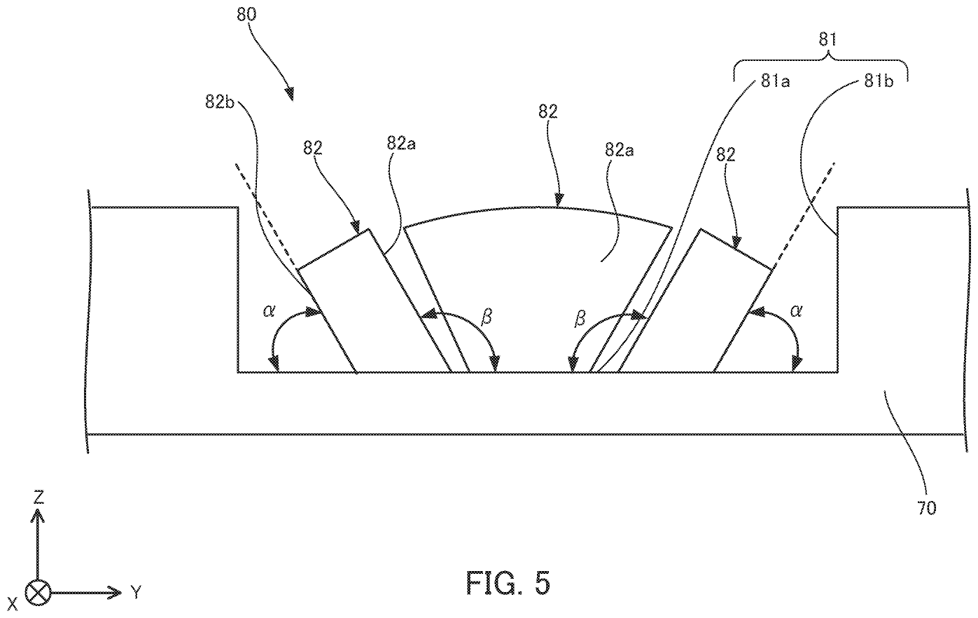

The following describes the interlocking portions 80 formed in the cooling plate 70 with reference to FIGS. 4 and 5. FIG. 4 is a perspective view of an interlocking portion formed in a cooling plate provided in the semiconductor device according to the first embodiment. FIG. 5 is a sectional view of the interlocking portion formed in the cooling plate provided in the semiconductor device according to the first embodiment. In this connection, FIG. 4 is an enlarged view of the interlocking portion 80 formed in the cooling plate 70 of FIG. 1, and FIG. 5 is a sectional view taken along the dot-dashed line X1-X1 of FIG. 4.

The interlocking portion 80 includes a U-shaped recess 81 formed in the front surface of the cooling plate 70 and a plurality (four in FIGS. 4 and 5) of projections 82 formed inside the recess 81. The recess 81 has a U shape with a recess bottom surface 81a and a loop-shaped inner wall 81b along the perimeter of the recess bottom surface 81a.

The recess bottom surface 81a is positioned lower (in the negative Z direction) than the front surface of the cooling plate 70. The recess bottom surface 81a is preferably substantially circular in plan view. Alternatively, the recess bottom surface 81a may have a distorted circular shape, an elliptical shape, or a rectangular shape with R-shaped corners, for example, depending on the processed state of the recess 81. In addition, the recess bottom surface 81a is preferably substantially parallel to the front surface of the cooling plate 70. Alternatively, the recess bottom surface 81a may be inclined with respect to the rear surface of the cooling plate 70 or may be rough with bumps and dips, not be flat, depending on the processed state of the recess 81. In this connection, the depth of the recess 81 may be in the range of 10.0% to 90.0% of the thickness of the cooling plate 70, inclusive. Here, the depth of the recess 81 refers to the height from the lowest point of the recess bottom surface 81a to the front surface of the cooling plate 70.

The inner wall 81b is preferably substantially perpendicular to the front surface of the cooling plate 70. The upper part of the inner wall 81b on the top side (the side closer to the front surface of the cooling plate 70) of the recess 81 may be wider than the lower part thereof on the bottom side (the side closer to the rear surface of the cooling plate 70) of the recess 81, depending on the processed state of the recess 81. The inner wall 81b does not necessarily expand symmetrically. In addition, the juncture between the inner wall 81b and the recess bottom surface 81a preferably does not have the right angle but has an R-shape. This allows the sealing member 68 to fill the interlocking portion 80 up to the juncture between the inner wall 81b and the recess bottom surface 81a without producing air voids. Air voids, if produced, may degrade the cooling property of the cooling plate 70 and reduce the adhesion of the sealing member 68 to the interlocking portion 80. The upper part of the inner wall 81b on the top side (the side closer to the front surface of the cooling plate 70) of the recess 81 may be narrower than the lower part thereof on the bottom side (the side closer to the rear surface of the cooling plate 70) of the recess 81. The inner wall 81b of this type will be described later.

The projections 82 are made of the same material as the cooling plate 70. For example, the projections 82 are block-shaped and are formed, for example, by approximately equally dividing a cylindrical member into four in plan view and tilting the four blocks to the outside. That is, the plurality of projections 82 are arranged in a loop shape along the inner wall 81b on the recess bottom surface 81a. In this connection, the quantity of the blocks is just an example. The projections 82 each have an engagement surface 82b and an inner surface 82a. The engagement surfaces 82b and inner surfaces 82a are curved so as to bulge toward the inner wall 81b. The engagement surfaces 82b face the inner wall 81b and the inner surfaces 82a face the center of the recess bottom surface 81a. The engagement surfaces 82b are inclined at an acute angle with respect to the front surface of the cooling plate 70. FIGS. 4 and 5 illustrate the case where the front surface of the cooling plate 70 and the recess bottom surface 81a are approximately parallel to each other. Therefore, the engagement surfaces 82b are inclined at the acute angle with respect to the recess bottom surface 81a. In this connection, this inclination angle α is preferably in the range of 45 degrees to 85 degrees, inclusive. The inclination angle β of the inner surfaces 82a is therefore defined as 180 degrees minus inclination angle α. In this connection, the junctures between the surfaces of each projection 82 do not necessarily have the right angle but may have an R-shape. In addition, the projections 82 tilted as described above do not project beyond the front surface of the cooling plate 70 from the recess 81. In addition, each surface connecting an engagement surface 82b and an inner surface 82a, adjacent to one of the projections 82, may be inclined at an acute angle with respect to the recess bottom surface 81a.

When the sealing member 68 is applied onto the cooling plate 70 having the above interlocking portions 80 formed in the front surface thereof, the sealing member 68 enters the recesses 81 of the interlocking portions 80. By filling the recesses 81 with the sealing member 68, the projections 82 are sealed with the sealing member 68 as well. The sealing member 68 also seals the inside of the case 60 and is solidified. If the adhesion of the sealing member 68 to the cooling plate 70 reduces as time passes, the sealing member 68 may be separated from the front surface of the cooling plate 70. In addition, stress is generated due to the differences in thermal expansion coefficient among the cooling plate 70, case 60, and sealing member 68 in the semiconductor device 10. Especially, the stress is likely concentrated on the corners of the case 60. Such stress may facilitate the separation of the sealing member 68.

To deal with this, in the semiconductor device 10, the projections 82 having the inclined engagement surfaces 82b are sealed with the sealing member 68, and the inclination of the engagement surfaces 82b produces an anchoring effect in sealing with the sealing member 68. More specifically, in the recess 81 of each interlocking portion 80, the sealing member 68 acting to separate in the positive Z direction is resisted in the negative Z direction by the inclined engagement surfaces 82b of the projections 82. The projections 82 engage with the sealing member 68 by means of the engagement surfaces 82b. Especially, the interlocking portions 80 of the semiconductor device 10 are formed at the four corners of the cooling plate 70 to which the case 60 is attached. Therefore, the semiconductor device 10 is able to prevent the sealing member 68 from separating from the cooling plate 70. In this connection, in order to prevent the separation of the sealing member 68, at least one interlocking portion 80 needs to be formed in a free space of the cooling plate 70 on which the semiconductor unit 50 is mounted. As described above, it is preferable that the interlocking portions 80 be formed at the four corners of the cooling plate 70 to which the case 60 is attached.

If projections 82 that each have the engagement surface 82b but that have a shape of inverted circular truncated cone (or a shape of funnel) without any gap therebetween or the hollow 83 are formed in a recess 81, the sealing member 68 is not likely to enter the gaps between the projections 82 and the recess 81 depending on the sizes of the projections 82, which may produce air voids. By contrast, referring to FIGS. 4 and 5, the plurality (four) of projections 82 are formed in a loop shape with a gap therebetween. In addition, the projections 82 surround the hollow 83. This configuration allows the projections 82 to be coated well with the filling sealing member 68, so that the projections 82 are sealed properly. In addition, even when the projections 82 expand toward the inner wall 81b in the recess 81, the gaps between the projections 82 and the hollow 83 allow the sealing member 68 to seal the recess 81 properly. Since the interlocking portions 80 are sealed with the sealing member 68 properly, the engagement surfaces 82b of the projections 82 are able to achieve an effect of preventing the separation of the sealing member 68 easily.

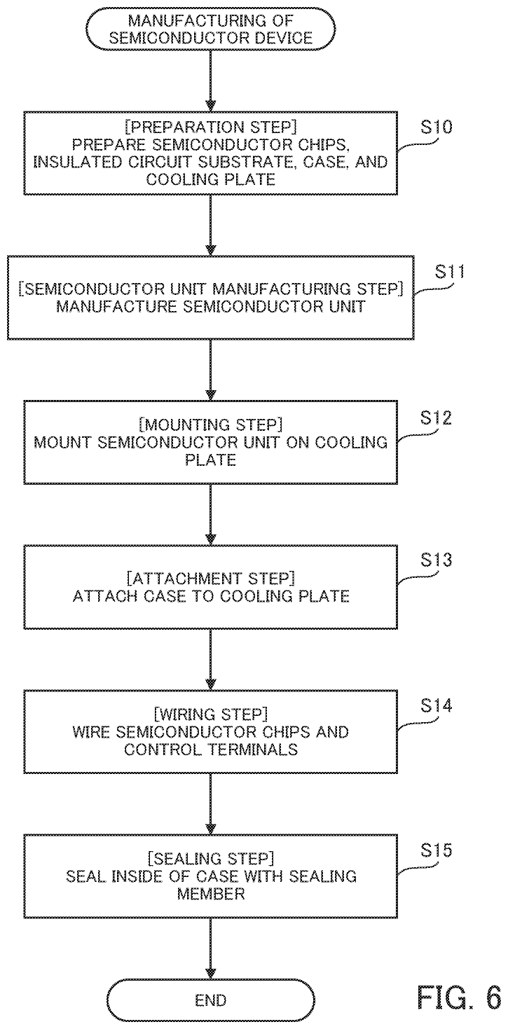

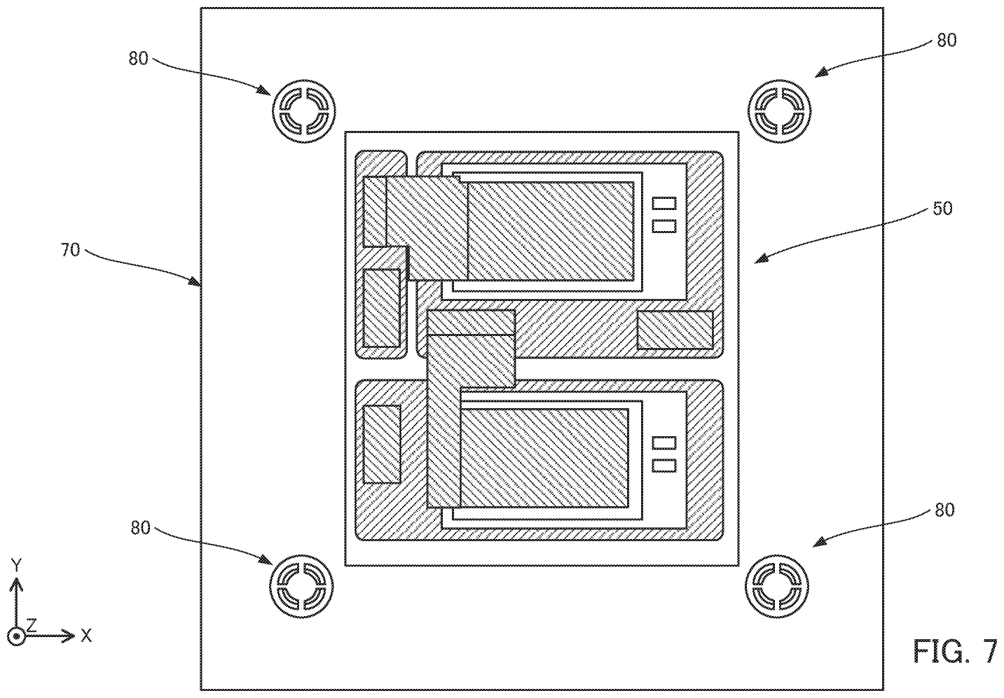

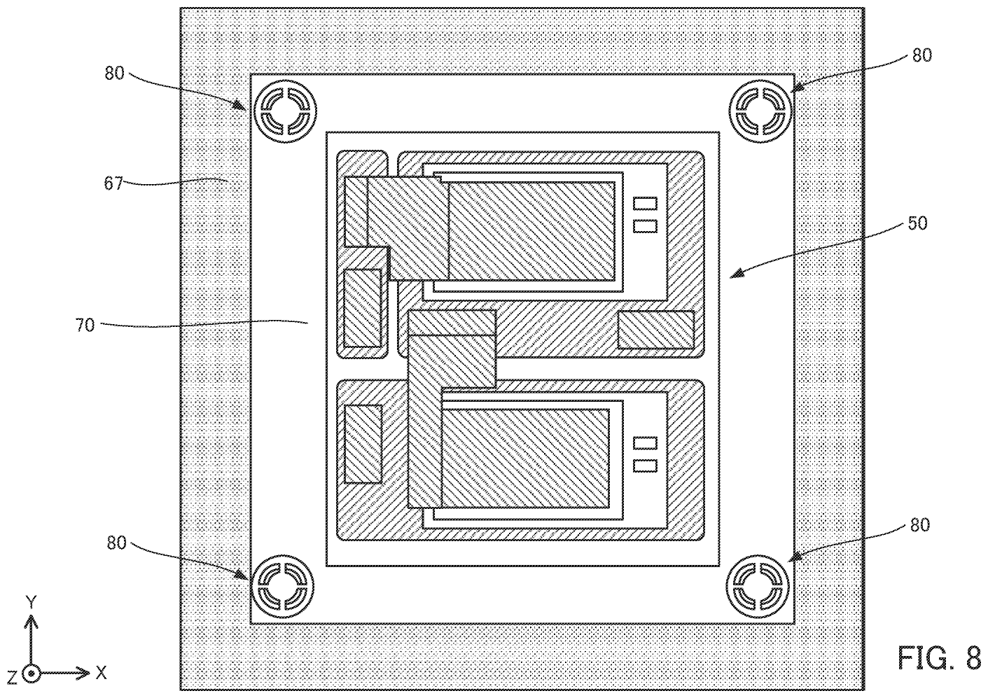

The following describes a method of manufacturing the above-described semiconductor device 10 with reference to FIGS. 6 to 8 and FIGS. 1 and 2. FIG. 6 is a flowchart illustrating a method of manufacturing the semiconductor device according to the first embodiment. FIG. 7 is a view for describing a mounting step included in the method of manufacturing the semiconductor device according to the first embodiment. FIG. 8 is a view for describing an attachment step included in the method of manufacturing the semiconductor device according to the first embodiment.

First, a preparation step of preparing components of the semiconductor device 10 is performed (step S10). In this preparation step, at least the semiconductor chips 30, insulated circuit substrate 20, case 60, and cooling plate 70, which are components of the semiconductor device 10, are prepared. The case 60 is integrally formed with the external connection terminals 63, 64, and 65 and control terminals 66a and 66b in advance. In addition, the interlocking portions 80 are formed in the front surface of the cooling plate 70 in advance. The method of manufacturing the cooling plate 70 will be described later.

Then, a semiconductor unit manufacturing step of manufacturing the semiconductor unit 50 using the components prepared at step S10 is performed (step S11). The insulated circuit substrate 20 is set in a predetermined fixing jig, and the semiconductor chips 30 are mounted on the circuit patterns 22a and 22b of the insulated circuit substrate 20 via a bonding member and the conduction blocks 24a, 24b, and 24c are mounted on the circuit patterns 22a, 22b, and 22c via the bonding member. In addition, one end of the wiring member 40 is mounted on the circuit pattern 22c via the bonding member and the other end thereof is mounted on the output electrode 31 of the semiconductor chip 30 on the circuit pattern 22b via the bonding member. One end of the wiring member 41 is mounted on the circuit pattern 22b via the bonding member and the other end thereof is mounted on the output electrode 31 of the semiconductor chip 30 on the circuit pattern 22a via the bonding member. For example, in the case of using a solder sheet as the bonding member, the unit obtained by the above mounting is heated to melt the solder sheet and then is cooled to solidify the melt solder, so that the bonding is achieved. In the way described above, the semiconductor unit 50 is manufactured.

Then, a mounting step of mounting the semiconductor unit 50 on the cooling plate 70 is performed (step S12). As illustrated in FIG. 7, the semiconductor unit 50 is mounted on a mounting area (the central area in FIG. 7) of the cooling plate 70 via the bonding member 52. In the case of using a solder sheet as the bonding member, the unit obtained by the mounting is heated to melt the solder sheet and is then cooled to solidify the solder, so that the semiconductor unit 50 is bonded to the cooling plate 70.

Then, an attachment step of attaching the case 60 to the cooling plate 70 on which the semiconductor unit 50 is mounted is performed (step S13). As illustrated in FIG. 8, an adhesive 67 is applied in a loop shape along the outer edge of the cooling plate 70 on which the semiconductor unit 50 is mounted. The application area is where the case 60 is to be attached and is the outer edge of the cooling plate 70 outside the interlocking portions 80. The case 60 is attached onto the adhesive 67 of the cooling plate 70. When the case 60 is attached to the cooling plate 70, one end of each external connection terminal 63, 64, and 65 inside the case 60 gets into contact with the front surface of the corresponding one of the conduction blocks 24c, 24a, and 24b. The one end of each external connection terminal 63, 64, and 65 is bonded to the front surface of the corresponding one of the conduction blocks 24c, 24a, and 24b by laser welding (see FIG. 1).

Then, a wiring step of mechanically and electrically connecting the control electrodes 32 of the semiconductor chips 30 and the control terminals 66a and 66b with the wires 51 is performed (step S14). A bonding device is used for directly connecting the control electrode 32 of the semiconductor chip 30 on the circuit pattern 22a and the control terminals 66b on the terminal block 62b with the wires 51 (see FIG. 2). Similarly, the bonding device is used for directly connecting the control electrode 32 of the semiconductor chip 30 on the circuit pattern 22b and the control terminals 66a on the terminal block 62a with the wires 51.

Next, a sealing step of sealing the housing space 61i of the case 60 with the sealing member 68 is performed (step S15). An adhesion accelerant is applied over the entire surfaces of the case 60 in the housing space 61i. Examples of the adhesion accelerant include polyamide-based resins. Then, the housing space 61i of the case 60 is filled with the sealing member 68 to seal the semiconductor unit 50 and others. In the manner described above, the semiconductor device 10 is manufactured.

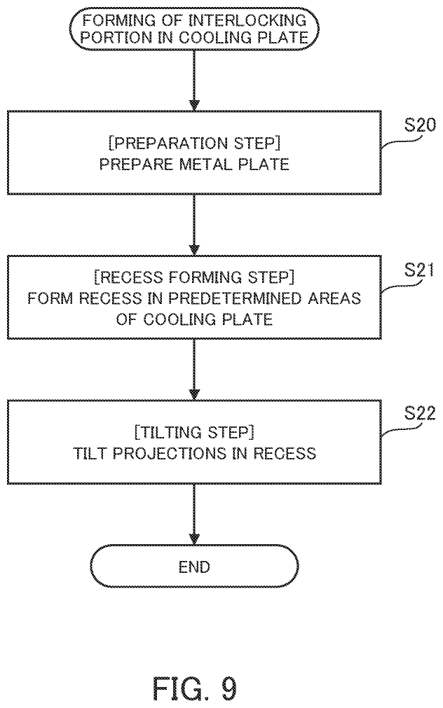

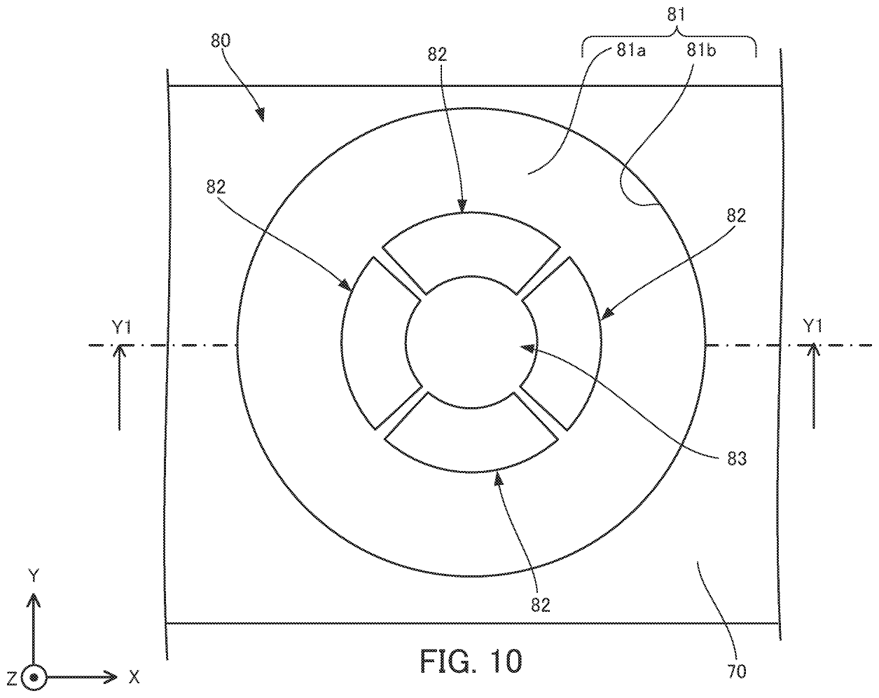

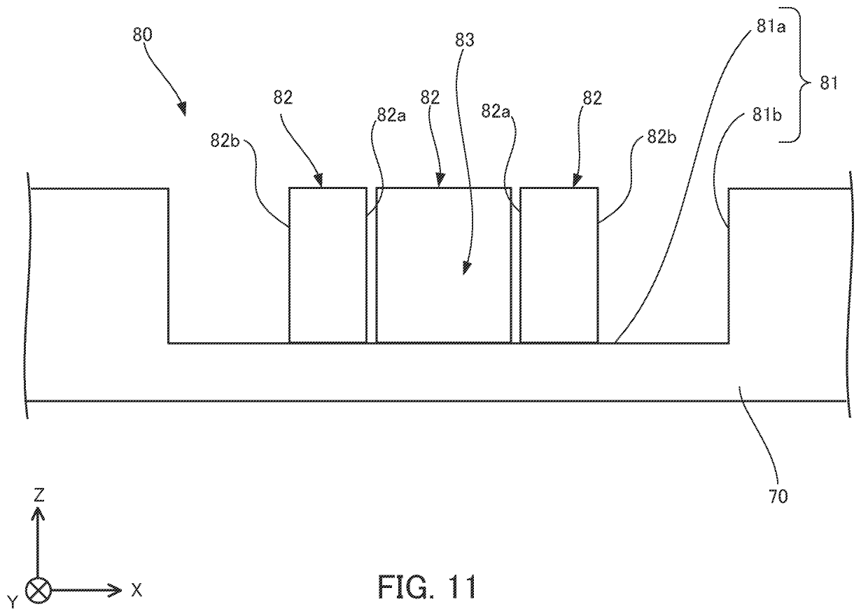

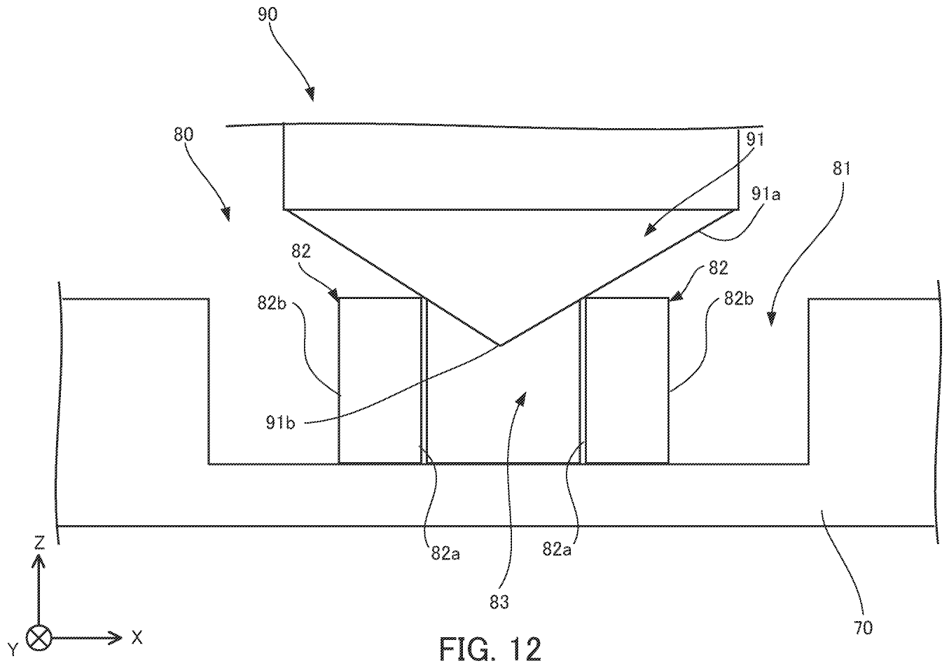

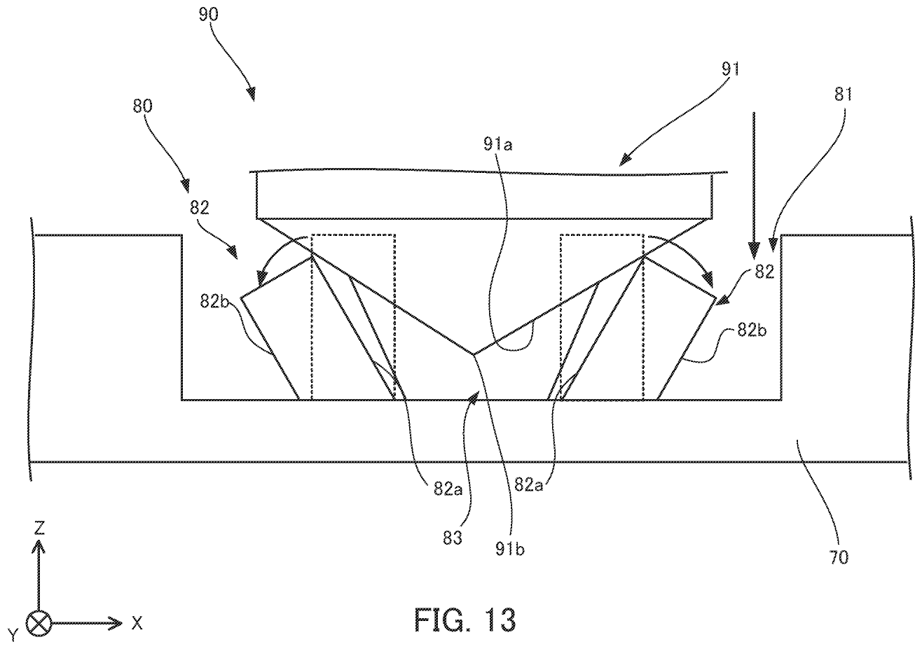

The following describes a method of manufacturing the cooling plate 70, which is prepared at step S10 of FIG. 6, with reference to FIGS. 9 to 13. FIG. 9 is a flowchart illustrating a method of forming an interlocking portion in a cooling plate according to the first embodiment. FIG. 10 is a plan view for describing a recess forming step included in the method of forming the interlocking portion in the cooling plate according to the first embodiment. FIG. 11 is a sectional view for describing the recess forming step included in the method of forming the interlocking portion in the cooling plate according to the first embodiment. FIGS. 12 and 13 are views for describing a tilting step included in the method of forming the interlocking portion in the cooling plate according to the first embodiment. In this connection, FIG. 11 is a sectional view taken along the dot-dashed line Y1-Y1 of FIG. 10. FIGS. 12 and 13 correspond to the sectional view of FIG. 11.

First, a preparation step of preparing a metal plate that is made into the cooling plate 70 is performed (step S20). The metal plate prepared here contains aluminum as a principal component, for example. A part corresponding to the cooling plate 70 is cut out from the metal plate. Hereinafter, the cutout is called the cooling plate 70.

Then, a recess forming step of forming a recess in a predetermined area of the cooling plate 70 prepared at step S20 is performed (step S21). Press processing using a predetermined mold is performed in predetermined areas (here, four areas located away from the four corners toward the center) of the cooling plate 70. By doing so, a recess 81 that is circular in plan view is formed as illustrated in FIGS. 10 and 11. In addition, on the recess bottom surface 81a of the recess 81, four projections 82 are formed at equal intervals in a loop shape along the inner wall 81b so as to surround the hollow 83. In this connection, the intervals between the projections 82 are set desirably. As long as the projections 82 are separated from each other, they may be in contact with each other. The four projections 82 form a cylinder with the hollow 83 inside. Therefore, as illustrated in FIG. 10, the inner surfaces 82a and engagement surfaces 82b are curved. These projections 82 integrally connect with the recess bottom surface 81a and extend vertically upward (in the positive Z direction) with respect to the front surface of the cooling plate 70. That is, the inner surfaces 82a of the projections 82 face the hollow 83 and the engagement surfaces 82b thereof face the inner wall 81b. In addition, the inner surfaces 82a, engagement surfaces 82b, and inner wall 81b are approximately parallel to each other.

Then, a tilting step of tilting the projections 82 is performed (step S22). To tilt the projections 82 extending vertically upward (in the positive Z direction) from the recess bottom surface 81a of the recess 81, a tilting jig 90 is used. The tilting jig 90 has a spire 91 at least at an end of the body part thereof. The spire 91 has an inclined surface 91a with an apex 91b. The inclined surface 91a has a circular shape with the apex 91b at the center in plan view. In this connection, the inclined surface 91a is not limited to be circular but may be rectangular in plan view. In addition, the area of the inclined surface 91a in plan view is preferably greater than that of the projections 82 arranged in a loop shape in plan view. In side view, the apex 91b of the inclined surface 91a has a predetermined angle. This angle is set so that, when the apex 91b of the spire 91 is inserted into the hollow 83, the apex 91b is positioned above (in the positive Z direction) the center of the hollow 83 (in terms of the height in the Z direction). In addition, the apex 91b is not necessarily made sharp as long as the apex 91b is able to be inserted into the hollow 83.

The apex 91b of the spire 91 of the above tilting jig 90 is aligned with the center of the hollow 83. The tilting jig 90 is then moved toward the metal plate (in the negative Z direction) until the tilting jig 90 gets into contact with the projections 82. Then, the tilting jig 90 is pressed toward the cooling plate 70 (in the negative Z direction). Since the projections 82 are pressed by the inclined surface 91a to the outside (toward the inner wall 81b), the projections 82 are tilted, as illustrated in FIG. 13. At this time, the projections 82 are tilted to the outside (toward the inner wall 81b) simultaneously. The tilt angle of the projections 82 depends on the pressing distance of the tilting jig 90, the angle of the apex 91b, and others. In this connection, the use of the tilting jig 90 for tilting the projections 82 is just an example. Alternatively, for example, the projections 82 may be tilted by being bent one by one to the outside. However, the use of the tilting jig 90 is able to tilt the plurality of projections 82 simultaneously, so that the cooling plate 70 is manufactured efficiently. In the manner described above, the cooling plate 70 is obtained, in which the interlocking portions 80 each including the recess 81 and the projections 82 having the inclined engagement surfaces 82b in the recess 81 are formed.

The above-described semiconductor device 10 has the semiconductor unit 50 including the semiconductor chips 30, the cooling plate 70 having the semiconductor unit 50 disposed on the front surface thereof, the case 60 disposed along the outer edge of the front surface of the cooling plate 70 at the outer edge via the adhesive 67 so as to surround the semiconductor unit 50, and the sealing member 68 sealing the semiconductor unit 50 on the cooling plate 70 inside the case 60. The cooling plate 70 has the interlocking portions 80 that each include the U-shaped recess 81 formed in the front surface of the cooling plate 70 and the engagement surfaces 82b formed inside the recess 81 and inclined at an acute angle with respect to the front surface of the cooling plate 70. In each interlocking portion 80 sealed with the sealing member 68, the engagement surfaces 82b of the projections 82 exhibit an anchoring effect in sealing with the sealing member 68. Therefore, the separation of the sealing member 68 from the cooling plate 70 is prevented.

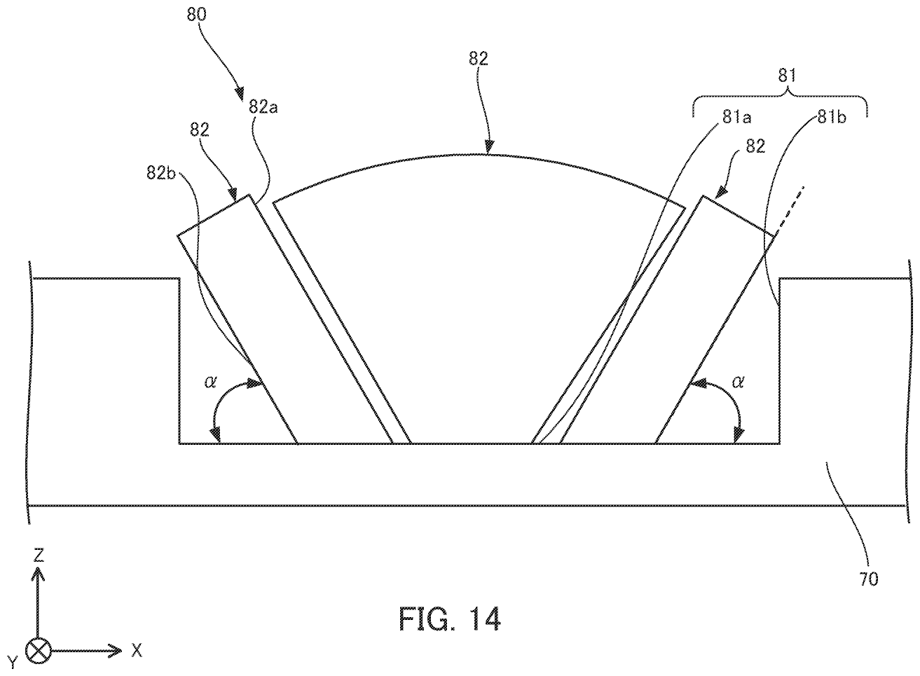

To prevent the separation of the sealing member 68 more reliably, it is preferable that the contact area of the projections 82 with the sealing member 68 be made as large as possible. Therefore, it is preferable that many interlocking portions 80 that are not so large as to reduce the strength of the cooling plate 70 be formed in available free areas of the cooling plate 70. The following describes a modification example that prevents the separation of the sealing member 68 more reliably with reference to FIG. 14.

### Modification Example 1-1

FIG. 14 is a sectional view of an interlocking portion formed in a cooling plate provided in a semiconductor device according to a modification example 1-1 of the first embodiment. In the interlocking portion 80 of the modification example 1-1, projections 82 extend beyond the front surface of a cooling plate 70. In this case, compared with the case of FIGS. 4 and 5, the contact area of engagement surfaces 82b with the sealing member 68 increases as the engagement surfaces 82b expand. Therefore, this case prevents the separation of the sealing member 68 more reliably than the case of FIGS. 4 and 5. In this connection, it is preferable that the projections 82 extend beyond the front surface of the cooling plate 70 without covering up the recess 81 in plan view.

### Second Embodiment

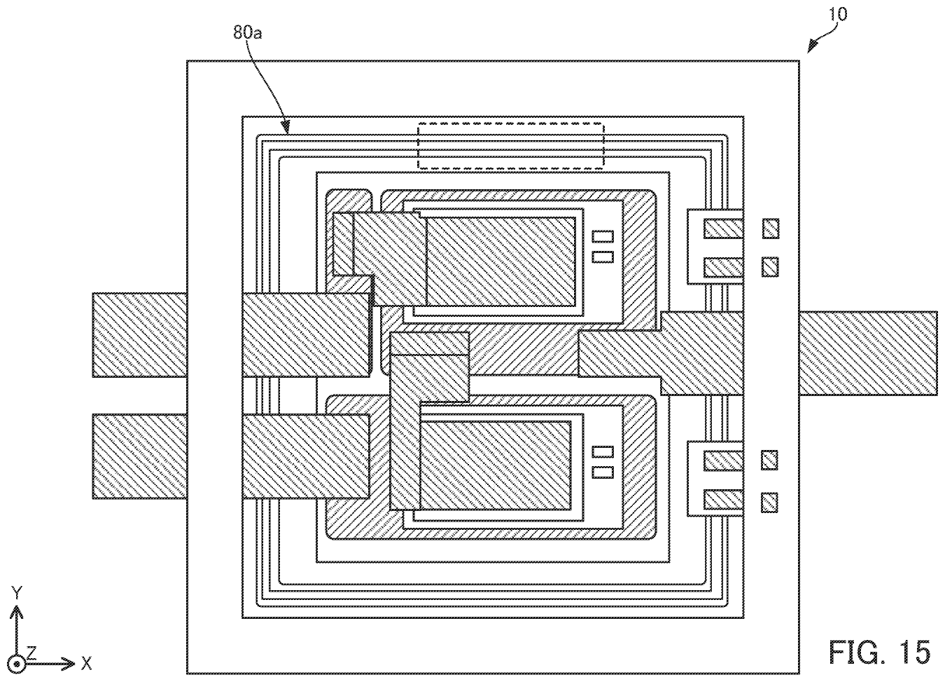

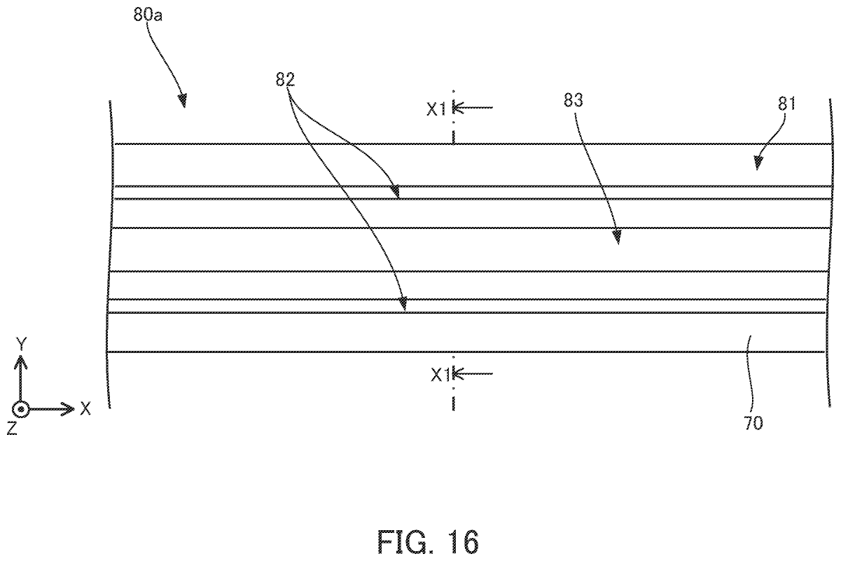

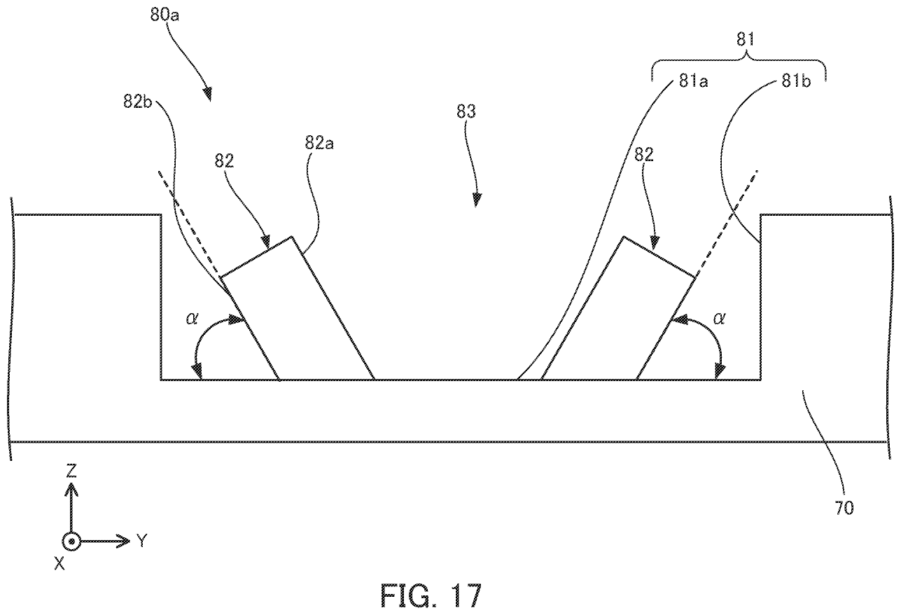

The second embodiment describes the case where an interlocking portion is formed in a loop shape along the case 60 in a cooling plate 70. This semiconductor device will be described with reference to FIGS. 15 to 17. FIG. 15 is a plan view of a semiconductor device according to the second embodiment. FIG. 16 is a plan view of an interlocking portion formed in a cooling plate provided in the semiconductor device according to the second embodiment. FIG. 17 is a sectional view of the interlocking portion formed in the cooling plate provided in the semiconductor device according to the second embodiment. In this connection, FIG. 16 is an enlarged plan view of an area enclosed by the broken line of FIG. 15. FIG. 17 is a sectional view taken along the dot-dashed line X1-X1 of FIG. 16. In addition, the semiconductor device 10 of the second embodiment has the same configuration as the semiconductor device 10 of the first embodiment except an interlocking portion 80a. Therefore, reference numerals are given only to parts additionally needed for the following description, with omitting reference numerals for the same components.

In the semiconductor device 10 of the second embodiment, the interlocking portion 80a is continuously formed in a loop shape along the case 60 at the outer edge of the front surface of the cooling plate 70 to which the case 60 is attached. The interlocking portion 80a includes a recess 81 and two projections 82 formed in the recess 81, as illustrated in FIG. 16. The recess 81 is a groove-like recess that is formed continuously in a loop shape at the outer edge of the front surface of the cooling plate 70. The recess 81 has a recess bottom surface 81a and opposite inner walls 81b.

In plan view, the recess bottom surface 81a has a continuous loop shape and has sides substantially parallel to the respective sides of the cooling plate 70. In this connection, each side of the recess bottom surface 81a is not necessarily parallel to the corresponding side of the cooling plate 70 but may have some angle with respect to the side, depending on the processed state of the recess 81. In addition, each corner of the recess bottom surface 81a does not necessarily have the right angle but may have an R shape. In addition, the width (the length in the Y direction of FIG. 16) of the recess bottom surface 81a is made substantially constant as a whole, or may vary. Depending on the processed state of the recess 81, the recess bottom surface 81a may be inclined with respect to the rear surface of the cooling plate 70, or may be rough with bumps and dips, not be flat. In this connection, the depth of the recess 81 is in the range of 10.0% to 90.0% of the thickness of the cooling plate 70, inclusive. Here, the depth of the recess 81 refers to the height from the lowest point of the recess bottom surface 81a to the front surface of the cooling plate 70.

The inner walls 81b are preferably substantially perpendicular to the front surface of the cooling plate 70. Depending on the processed state of the recess 81, the upper space between the inner walls 81b on the top side (the side closer to the front surface of the cooling plate 70) of the recess 81 may be wider than the lower space therebetween on the bottom side (the side closer to the rear surface of the cooling plate 70) of the recess 81. The space between the inner walls 81b does not necessarily widen symmetrically. In addition, the junctures between the inner walls 81b and the recess bottom surface 81a preferably do not have the right angle but have an R-shape. The upper space between the inner walls 81b on the top side (the side closer to the front surface of the cooling plate 70) of the recess 81 may be narrower than the lower space therebetween on the bottom side (the side closer to the rear surface of the cooling plate 70) of the recess 81. The inner walls 81b of this type will be described later.

The two projections 82 may be made of the same material as the cooling plate 70. The two projections 82 have a flat plate shape and are formed continuously in a loop shape along the inner walls 81b on the recess bottom surface 81a. The two projections 82 each have an I-shaped cross section and the upper parts thereof (on the side closer to the opening of the recess 81) are tilted toward the inner walls 81b. These projections 82 each have an engagement surface 82b and an inner surface 82a. Their engagement surfaces 82b face the inner walls 81b and their inner surfaces 82a face each other. In this connection, a hollow 83 is sandwiched between the inner surfaces 82a of the two projections 82. The engagement surfaces 82b are inclined at an acute angle with respect to the front surface of the cooling plate 70. The engagement surfaces 82b are inclined in the same manner as the engagement surfaces 82b of the first embodiment. The projections 82 tilted as described above do not project beyond the front surface of the cooling plate 70 from the recess 81.

The above interlocking portion 80a is formed in accordance with the flowchart of FIG. 9 as in the first embodiment. More specifically, the recess forming step of forming a recess along the attachment area for the case 60 in the cooling plate 70 prepared at step S20 is performed (step S21). Press processing using a predetermined mold is performed in an area of the cooling plate 70 along the case 60. Thereby, the groove-like recess 81 is formed. In addition, the two projections 82 are formed in parallel to each other in a loop shape along the inner walls 81b on the recess bottom surface 81a of the recess 81 so as to sandwich the hollow 83. The two projections 82 integrally connect with the recess bottom surface 81a and extend vertically upward (in the positive Z direction) with respect to the front surface of the cooling plate 70. That is, the inner surfaces 82a of the projections 82 face the hollow 83, and the engagement surfaces 82b thereof face the inner walls 81b. In addition, the inner surfaces 82a, engagement surfaces 82b, and inner walls 81b are approximately parallel to each other.

Then, the tilting step of tilting the projections 82 is performed (step S22). To tilt the projections 82 extending vertically upward (in the positive Z direction) from the recess bottom surface 81a of the recess 81, a tilting jig 90 is used. The tilting jig 90 of this case has a spire 91 at least at an end of the body part thereof as well. The spire 91 has a loop shape in plan view and has an inclined surface 91a with an apex 91b. That is, the tilting jig 90 that has a cross section illustrated in FIG. 12 is formed to have the loop shape. In side view, the apex 91b of the inclined surface 91a has a predetermined angle. This angle is set so that, as illustrated in FIG. 12, when the apex 91b of the spire 91 is inserted into the hollow 83, the apex 91b is positioned above (in the positive Z direction) the center of the hollow 83 (in terms of the height in the Z direction). In addition, the apex 91b is not necessarily made sharp as long as it is able to be inserted into the hollow 83.

By pressing this tilting jig 90 toward the cooling plate 70 as in the first embodiment, the projections 82 are tilted as illustrated in FIG. 17. In addition, the two projections 82 are tilted to the outside (toward the inner wall 81b) simultaneously. Alternatively, for example, the projections 82 may be tilted by being bent one by one to the outside. However, the use of the tilting jig 90 makes it possible to tilt the plurality of projections 82 simultaneously, so that the cooling plate 70 is manufactured efficiently. In the manner described above, the cooling plate 70 is obtained, which has the interlocking portion 80a including the recess 81 and the projections 82 having the inclined engagement surfaces 82b in the recess 81.

In the semiconductor device 10 of the second embodiment, the inclination of the engagement surfaces 82b of the projections 82 sealed with the sealing member 68 provides an anchoring effect in sealing with the sealing member 68. In addition, the interlocking portion 80a of the semiconductor device 10 of the second embodiment is formed in a loop shape including the four corners of the cooling plate 70 to which the case 60 is attached. Therefore, the semiconductor device 10 of the second embodiment prevents the separation of the sealing member 68 from the cooling plate 70. In this connection, the interlocking portion 80a of the second embodiment may be formed in an L shape in plan view in the vicinity of a corner of the cooling plate 70 to which the case 60 is attached, not in a loop shape along the case 60 in the cooling plate 70. In addition, the two projections 82 may extend beyond the front surface of the cooling plate 70 as in the modification example 1-1 of the first embodiment.

### Modification Example 2-1

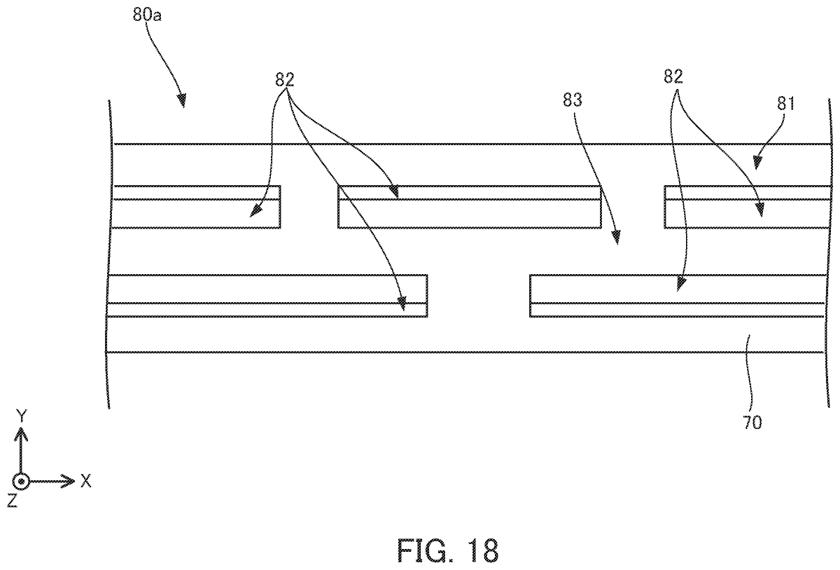

A modification example 2-1 of the second embodiment describes the case where two rows of projections 82 are formed so as to each form a broken line, not a continuous line, unlike the case of FIG. 16, with reference to FIG. 18. FIG. 18 is a plan view of an interlocking portion formed in a cooling plate provided in a semiconductor device according to the modification example 2-1 of the second embodiment.

In an interlocking portion 80a, each of the two projections 82 of FIG. 16 do not necessarily form a continuous line. As illustrated in FIG. 18, two rows of projections 82 that each form a broken line may be formed in a loop shape at the outer edge of the cooling plate 70. As described in the first embodiment, the projections 82 of each row having a gap therebetween are easily sealed with a sealing member 68, and the recess 81 is also easily sealed with the sealing member 68. Especially, by alternately arranging the gaps between the projections 82 of the two rows, it becomes easier to achieve the sealing with the sealing member 68.

### Third Embodiment

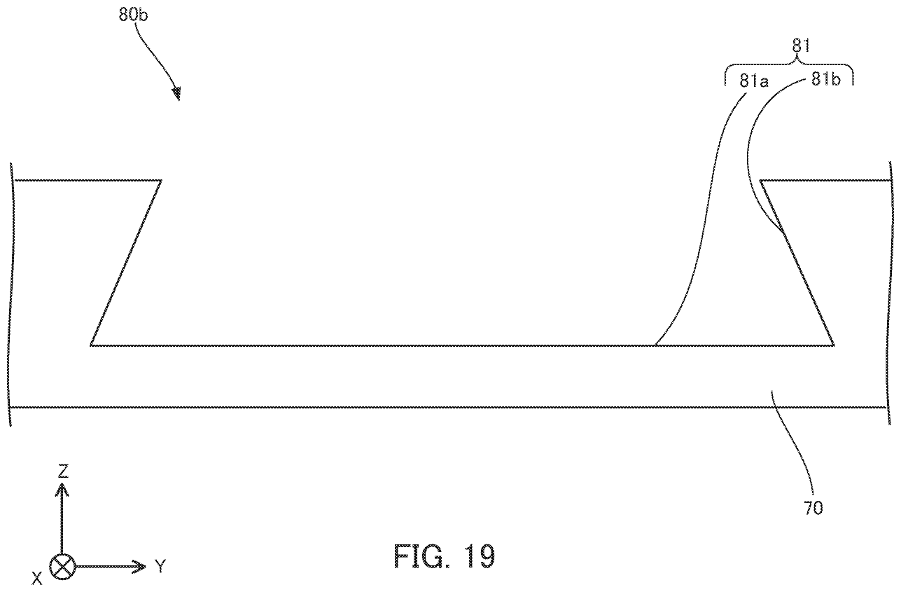

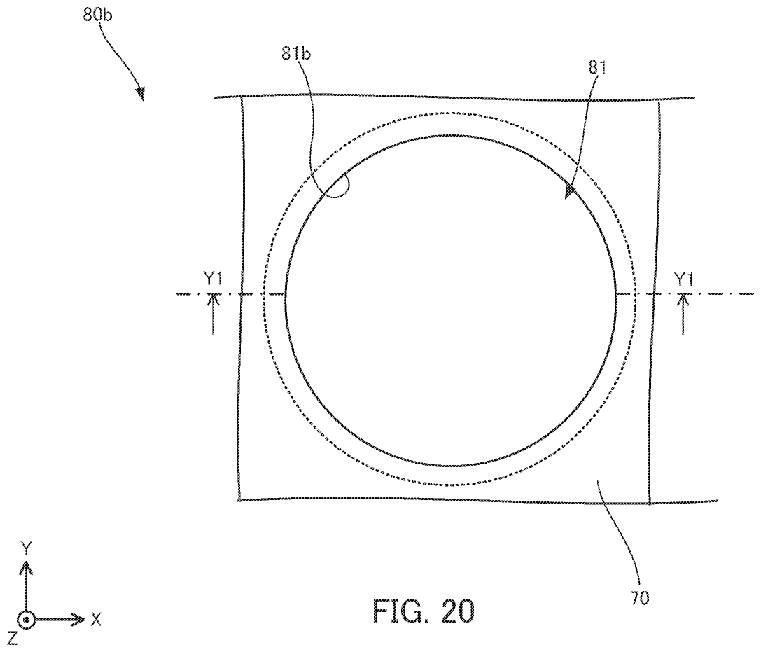

A third embodiment describes the case where the inner wall of the recess of each interlocking portion formed in the semiconductor device 10 of the first embodiment is inclined. This interlocking portion will be described with reference to FIGS. 19 and 20. FIG. 19 is a sectional view of an interlocking portion formed in a cooling plate provided in a semiconductor device according to the third embodiment. FIG. 20 is a plan view of the interlocking portion formed in the cooling plate provided in the semiconductor device according to the third embodiment. In this connection, FIG. 19 is a sectional view taken along the dot-dashed line Y1-Y1 of FIG. 20. Expect for interlocking portions 80b of the third embodiment, please refer to the semiconductor device 10 of the first embodiment.

Unlike the interlocking portion 80 of the first embodiment, each interlocking portion 80b formed in the semiconductor device 10 of the third embodiment does not have projections 82, and the inner wall 81b of a recess 81 is inclined at an acute angle with respect to the front surface of the cooling plate 70. That is, the inner wall 81b is inclined as in the interlocking portion 80 of the first embodiment.

In the semiconductor device 10 including the cooling plate 70 having the above interlocking portion 80b formed therein, the inclination of the inner wall 81b of the interlocking portion 80b sealed with a sealing member 68 provides an anchoring effect in sealing with the sealing member 68. That is, in the recess 81 of the interlocking portion 80b, the sealing member 68 acting to separate in the positive Z direction is resisted in the negative Z direction by the inclined inner wall 81b of the recess 81. The recess 81 engages with the sealing member 68 by means of the inner wall 81b. Therefore, the semiconductor device 10 prevents the sealing member 68 from separating from the cooling plate 70.

Note that, with respect to the second embodiment, the inner walls 81b of the recess 81 in the interlocking portion 80a may be inclined as in the third embodiment, except for the projections 82. In addition, only some parts of the inner walls 81b of the recess 81 in the loop-shaped interlocking portion 80a may be inclined. For example, in the loop-shaped interlocking portion 80a, only the long-side parts or short-side parts of the inner walls 81b may be inclined. Not inclining the inner walls 81b at the corners makes it possible to seal the corners with the sealing member 68 properly. Alternatively, only the inner circumference side inner wall 81b or the outer circumference side inner wall 81b of the recess 81 of the loop-shaped interlocking portion 80a may be inclined. Note that, to prevent the separation of the sealing member 68 reliably, it is preferable that the inclined area of the inner walls 81b be large in the loop-shaped interlocking portion 80a.

### Fourth Embodiment

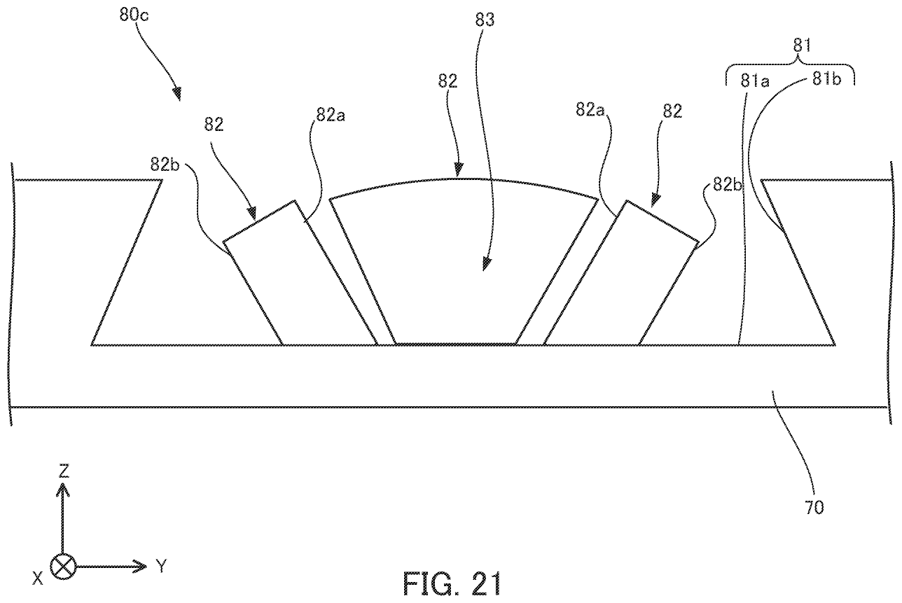

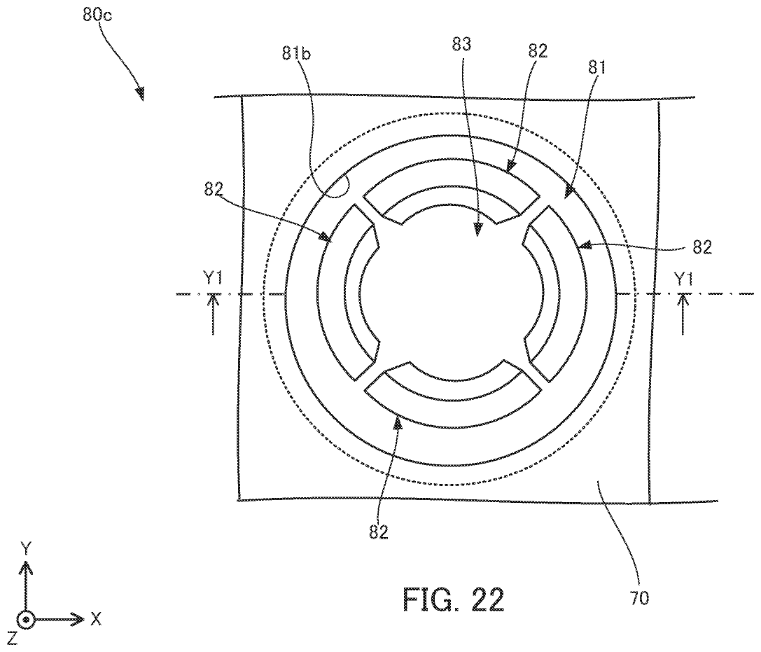

A fourth embodiment describes the case where the projections 82 of the first embodiment are formed in the recess 81 of each interlocking portion 80b of the third embodiment. An interlocking portion of this type will be described with reference to FIGS. 21 and 22. FIG. 21 is a sectional view of an interlocking portion formed in a cooling plate provided in a semiconductor device according to the fourth embodiment. FIG. 22 is a plan view of the interlocking portion formed in the cooling plate provided in the semiconductor device according to the fourth embodiment. In this connection, FIG. 21 is sectional view taken along the dot-dashed line Y1-Y1 of FIG. 22. Except for interlocking portions 80c of the fourth embodiment, please refer to the semiconductor device 10 of the first embodiment.

Each interlocking portion 80c formed in the semiconductor device 10 of the fourth embodiment is obtained by forming the projections 82 of the first embodiment on the recess bottom surface 81a of the recess 81 in the interlocking portion 80b of the third embodiment. That is, the projections 82 are tiled at an acute angle with respect to the front surface of the cooling plate 70, and the inner wall 81b of the recess 81 is inclined at an acute angle with respect to the front surface of the cooling plate 70.

In the semiconductor device 10 including the cooling plate 70 having the above interlocking portion 80c formed therein, the inclination of the inner wall 81b and the tilting of the projections 82 in the interlocking portion 80c sealed with a sealing member 68 provide an anchoring effect in sealing with the sealing member 68. That is, in the recess 81 of the interlocking portion 80c, the sealing member 68 acting to separate in the positive Z direction is resisted in the negative Z direction by the inclined inner wall 81b of the recess 81 and the engagement surface 82b of the tilted projection 82. The recess 81 engages with the sealing member 68 by means of the inner wall 81b and projections 82. Therefore, the semiconductor device 10 prevents the sealing member 68 from separating from the cooling plate 70. Especially, in the interlocking portion 80c of the fourth embodiment, the inner wall 81b and the projections 82 in the recess 81 engage with the sealing member 68. Therefore, the fourth embodiment prevents the separation of the sealing member 68 more reliably than the first to third embodiments.

In the interlocking portion 80a of the second embodiment, the inner walls 81b of the recess 81 may be inclined with respect to the projections 82 being tilt, as in the fourth embodiment. In this case as well, in the loop-shaped interlocking portion 80a, the projections 82 are tilted and, for example, only the long-side parts or short-side parts of the inner walls 81b of the recess 81 may be inclined. Alternatively, only the inner circumference side inner wall 81b or the outer circumference side inner wall 81b of the recess 81 in the loop-shaped interlocking portion 80a may be inclined.

### Fifth Embodiment

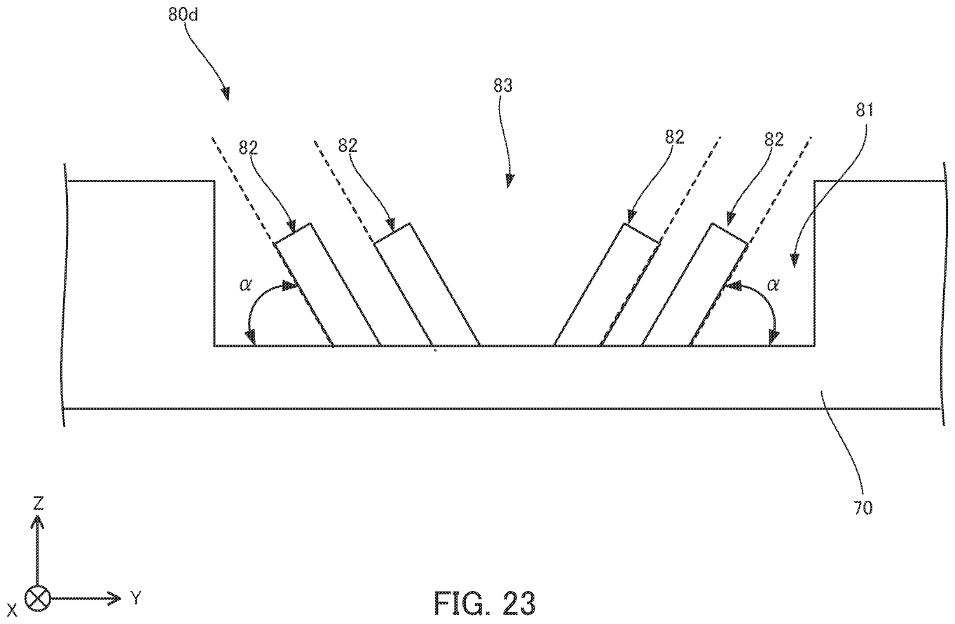

A fifth embodiment describes the case where a plurality of projections are formed in the radial direction or width direction in a recess. This interlocking portion will be described with reference to FIG. 23. FIG. 23 is a sectional view of an interlocking portion formed in a cooling plate provided in a semiconductor device according to the fifth embodiment. In this connection, FIG. 23 is a sectional view corresponding to FIGS. 5 and 17. In addition, except for an interlocking portion 80d, please refer to the semiconductor device 10 of the first embodiment for the semiconductor device 10 of the fifth embodiment.

The interlocking portion 80d formed in the semiconductor device 10 of the fifth embodiment is obtained by forming a plurality of projections 82 in the radial direction of the recess 81 in the interlocking portion 80 of the first embodiment. In this connection, FIG. 23 illustrates the case where the projections 82 are formed in the recess 81, with two projections illustrated in the right radial direction and two projections illustrated in the left radial direction in the recess 81.

On the other hand, in the light of the interlocking portion 80d of the fifth direction, a plurality of projections 82 are formed in the width direction of the recess 81 in the interlocking portion 80a of the second embodiment. In this connection, FIG. 23 corresponds to the case where the projections 82 are formed in the recess 81, with two projections illustrated in the right width direction and two projections illustrated in the left width direction in the recess 81.

In this case, as compared with the cases of FIGS. 5 and 17, with an increase in the number of engagement surfaces 82b, the contact area of the engagement surfaces 82b with the sealing member 68 increases. Therefore, this case prevents the separation of the sealing member 68 more reliably than the cases of FIGS. 5 and 17.

The disclosed technique improves the adhesion between a sealing member and a cooling plate and prevents a reduction in the reliability of a semiconductor device.

All examples and al language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor unit including a semiconductor chip;
a cooling plate having a cooling front surface on which the semiconductor unit is disposed;
a case disposed along an outer edge of the cooling front surface via an adhesive so as to surround the semiconductor unit; and
a sealing member sealing the semiconductor unit disposed on the cooling plate inside the case, wherein
the cooling plate has an interlocking portion, the interlocking portion including a recess in the cooling front surface, and an engagement surface disposed inside the recess and being inclined at an acute angle with respect to the cooling front surface.

2. The semiconductor device according to claim 1, wherein the semiconductor unit is laminated on the cooling plate, and the interlocking portion further includes a projection projecting from a recess bottom surface of the recess in a lamination direction in which the semiconductor unit is laminated on the cooling plate, the projection having the engagement surface, the recess bottom surface positioned below the cooling front surface in the lamination direction.

3. The semiconductor device according to claim 2, wherein the projection projects from the recess bottom surface above the cooling front surface in the lamination direction.

4. The semiconductor device according to claim 3, wherein the projection has an inner surface opposite to the engagement surface, and the inner surface and the engagement surface are both inclined with respect to the cooling front surface.

5. The semiconductor device according to claim 4, wherein the projection includes a plurality of projections projecting from the recess bottom surface and each having an engagement surface.

6. The semiconductor device according to claim 5, wherein the plurality of projections is formed in a loop shape at equal intervals with gaps therebetween, with the engagement surfaces facing an inner surface of the recess.

7. The semiconductor device according to claim 2, wherein
the recess is a groove-like recess that includes a linear portion extending in a linear direction parallel to the cooling front surface of the cooling plate, and
the engagement surface is parallel to the linear direction in which the linear portion of the recess extends in the recess.

8. The semiconductor device according to claim 7, wherein
the projection includes a pair of projections, each having its own engagement surface, disposed in the recess, and
the engagement surfaces of the pair of projections each face an inner surface of the recess.

9. The semiconductor device according to claim 1, wherein the engagement surface is disposed along an inner surface of the recess.

10. A method of manufacturing a semiconductor device, comprising:
preparing a semiconductor unit including a semiconductor chip, and a cooling plate having a cooling front surface;
forming a recess in the cooling front surface of the cooling plate and a projection that projects from a recess bottom surface of the recess in a lamination direction in which the cooling plate and the semiconductor unit are laminated inside the recess and that has an engagement surface parallel to the lamination direction and an inner surface opposite to the engagement surface, and
tilting the projection so that the engagement surface is inclined at an acute angle with respect to the cooling front surface;
after the forming and the tilting, mounting the semiconductor unit on the cooling front surface of the cooling plate, and a case along an outer edge of the cooling front surface at the outer edge via an adhesive so as to surround the semiconductor unit; and
sealing the semiconductor unit disposed on the cooling plate inside the case with a sealing member.

11. The method of manufacturing the semiconductor device according to claim 10, wherein
the projection includes a plurality of projections,
the forming includes forming the plurality of projections in a loop shape in the recess with engagement surfaces thereof each facing an inner surface of the recess, and
the tilting includes pressing the plurality of projections in an outward direction from a center of the projections toward the inner surface of the recess in order to tilt the plurality of projections.

12. The method of manufacturing the semiconductor device according to claim 11, wherein the tilting includes simultaneously pressing the plurality of projections in the outward direction.
